(19) United States
(12) Patent Application Publication
(10) Pub. No.: US 2011/0310565 A1
(43) Pub. Date: Dec. 22, 2011

(54) HEAT SINK FOR MEMORY MODULE

(75) Inventor: JIN-MIN HE, Shenzhen City (CN)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 12/939,298

(22) Filed: Nov. 4, 2010

(30) Foreign Application Priority Data
Jun. 17, 2010 (CN) 201020227461.X

(51) Int. Cl. H05K 7/20

(52) U.S. Cl. 361/715

(57) ABSTRACT

A heat sink for memory module includes two heat-sink plates and two fastening members. Each heat-sink plate defines two through holes. The through holes of one heat-sink plate are coaxial to the through holes of the other heat-sink plate. Each fastening member includes a first head portion and a second head portion. The first head portion is elastic and is allowed to be pushed to pass through the through holes. The two heat-sink plates are locked between the first head portion and the second head portion.

### BACKGROUND

1. Technical Field

The present disclosure relates to a heat sink for use with a memory module and for dissipating heat.

2. Description of Related Art

Memory modules are used in computers. With the continuous technical development of computers, larger and faster memory modules are being developed. As a result, the memory module radiates more heat. Heat sinks are generally applied to memory modules for dissipating heat. There are two conventional ways to attach the heat sinks to the memory module. One way is the heat sink is integrally formed with the memory module. However, in this way, the memory module inside the heat sink cannot be replaced. Another way is that the heat sink is divided into two parts with these two parts being fastened together with screws. However, in this way, it is too complicated to assemble or disassemble the heat sink.

Therefore, there is room for improvement within the art.

### BRIEF DESCRIPTION OF THE DRAWINGS

Many aspects of the heat sink can be better understood with reference to the following drawings. The components in the drawings are not necessarily drawn to scale, the emphasis instead being placed upon clearly illustrating the principles of the heat sink.

FIG. 1 is an assembled, isometric view of a heat sink, in accordance with an exemplary embodiment.

FIG. 2 is an exploded, isometric view of the heat sink shown in FIG. 1.

### DETAILED DESCRIPTION

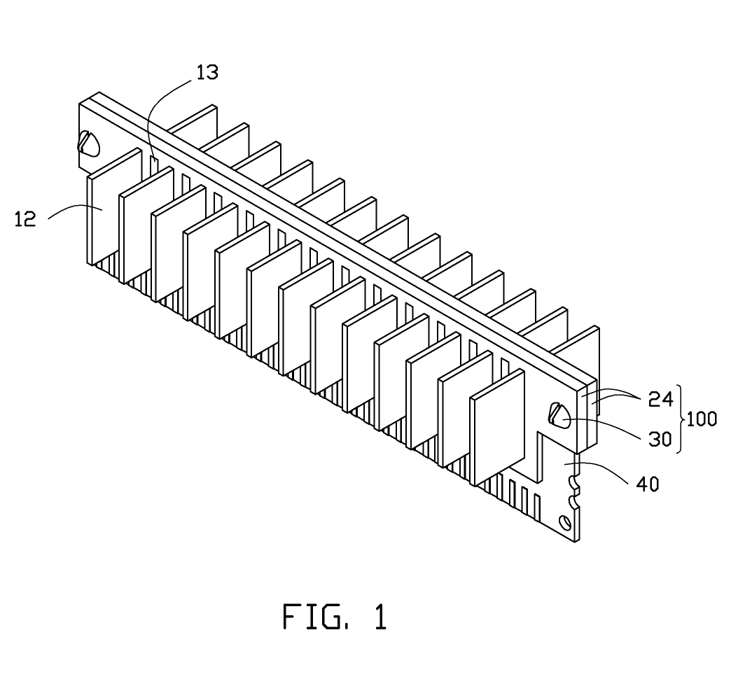

FIG. 1 shows an exemplary embodiment of a heat sink 100 attached to a memory module 40. The heat sink 100 includes two heat-sink plates 24 attached to the opposite sides of the memory module 40 and two fastening members 30 fastening together the two heat-sink plates 24.

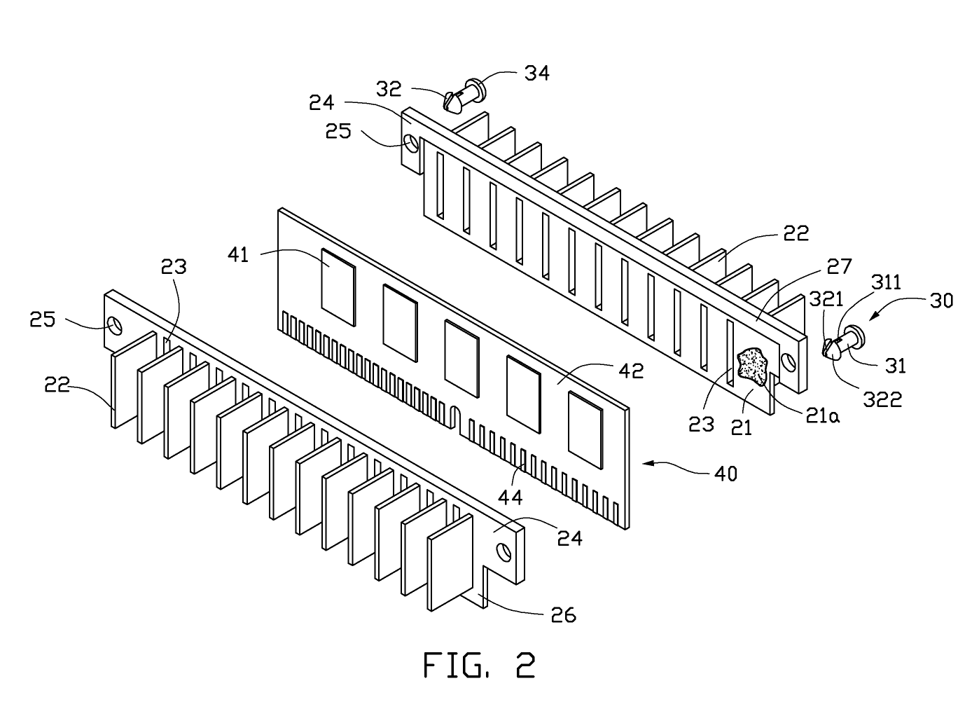

Also referring to FIG. 2, the memory module 40 includes a printed circuit plate 42 and a plurality of chips 41 mounted on the printed circuit plate 42. A plurality of connecting pads 44 are formed on a bottom of the printed circuit plate 42.

Each heat-sink plate 24 includes a first surface 26 and an opposite second surface 27. A number of spaced-apart fins 22 are formed on the first surface 26. The base plate 24 defines a number of grooves 23. Each two adjacent fins 22 have one of the grooves 23 positioned therebetween. The heat-sink plate 24 defines a recessed portion 21 in the second surface 27 for receiving the memory module 40 and which may be coated with thermal adhesive 21a (partially shown for clarity). Two ears 24 are formed at opposite ends of each heat-sink plate 24. Each ear 24 defines a through hole 25.

Each fastening member 30 includes a first head portion 32, a second head portion 34, and a shaft portion 31 connecting the first head portion 32 and the second head portion 34. The first head portion 32 is made of elastic material and may be conical. The fastening member 30 defines a slot 321 from the first head portion 32 to the shaft portion 31. The slot 321 divides the first head portion 32 into two parts 322 and the two parts 322 can be pushed together to extend through the through holes 25.

To attach the heat sinks 24 to the memory module 40, the two heat-sink plates 24 are positioned on opposite sides of the memory module 40. The two recessed portions 21 are combined to define a cavity to receive the chips 41. The connecting pads 44 extend out from the cavity. The through holes 25 of the heat-sink plates 24 are coaxially aligned to each other. The two parts 322 of the first head portion 32 are pushed together and pass through a pair of the through holes 25. The first head portion 32 then rebounds to the original shape, and the shaft portion 31 is received in the through holes 25. The two fastening members 30 are locked between the first head portions 32 and the second head portions 34, with the memory module 40 positioned therebetween. The thermal adhesive 21a can be used to further retain the memory modules between the heat sinks.

When the memory module 40 is in use, the heat radiating from the chips 41 runs out from the grooves 23 and dissipates with the fins 22.

To detach the sink from the memory module, the two parts 322 of each fastening member 30 are pushed together and are extracted from the pair of through holes 25. Thus, the memory module 40 can be replaced.

It is to be understood that even though numerous characteristics and advantages of the present embodiments have been set forth in the foregoing description, together with details of structures and functions of various embodiments, the disclosure is illustrative only, and changes may be made in detail, especially in matters of shape, size, and arrangement of parts within the principles of the present invention to the full extent indicated by the broad general meaning of the terms in which the appended claims are expressed.

What is claimed is:

1. A heat sink for memory module comprising:
two heat-sink plates, each heat-sink plate defining two through holes at opposite ends; and
two fastening members, each fastening member including a first head portion and a second head portion, the first head portion elastically passing through the holes, the two heat-sink plates locked between the first head portion and the second head portion.

2. The heat sink of claim 1, wherein each fastening member further comprises a shaft portion connecting the first head portion and the second head portion.

3. The heat sink of claim 2, wherein the fastening member defines a slot to divide the first head portion into two parts.

4. The heat sink of claim 3, wherein the first head portion is conical.

5. The heat sink of claim 1, wherein the heat-sink plate defines a plurality of grooves.

6. The heat sink of claim 5, wherein a plurality of fins are formed on one side of each heat-sink plate, and each two adjacent fins have one groove there between.

7. The heat sink of claim 6, wherein an ear is formed at each of two opposite ends of the heat-sink plate, and the through holes are defined in corresponding ears.

8. The heat sink of claim 7, wherein the base plate defines a recessed portion at another side.

9. The heat sink of claim 8, wherein the recessed portion has thermal adhesive mounted thereon.

10. A heat sink for memory module comprising:
two heat-sink plates, each heat-sink plate defining two through holes; and
two fastening members, each fastening member including a first head portion and a second head portion, the first head portion extending through a pair of the through holes and rebounding to original shape, the two heat-sink plates locked between the first head portion and the second head portion.

11. The heat sink of claim 10, wherein each fastening member further comprises a shaft portion connecting the first head portion and the second head portion.

12. The heat sink of claim 11, wherein the fastening member defines a slot to divide the first head portion into two parts.

13. The heat sink of claim 12, wherein the first head portion is corn shaped.

14. The heat sink of claim 10, wherein the heat-sink plate defines a plurality of grooves for allowing heat to run out.

15. The heat sink of claim 14, wherein a plurality of fins are formed on one side of each heat-sink plate, and each two adjacent fins have one groove there between.

16. The heat sink of claim 15, wherein an ear is formed at each of two opposite ends of the heat-sink plate, and the through holes are defined in corresponding ears.

17. A memory module assembly comprising:
a memory module;
two heat-sink plates mounted on two sides of the memory module, each heat-sink plate defining two through holes; and
two fastening members, each fastening member including a first head portion and a second head portion, the first head portion extending through a pair of the through holes and rebounding to original shape, the two heat-sink plates locked between the first head portion and the second head portion.

18. The memory module assembly of claim 7, wherein each heat-sink plate defines a recessed portion at another side, and the memory module is received in a combination of the two recessed portion.

19. The memory module assembly of claim 8, wherein the recessed portion has thermal adhesive mounted thereon.

20. The memory module assembly of claim 19, wherein each fastening member further comprises a shaft portion connecting the first head portion and the second head portion, and the fastening member defines a slot to divide the first head portion into two parts.
